(19) United States
(12) Patent Application Publication
(10) Pub. No.: US 2019/0244979 A1
(43) Pub. Date: Aug. 8, 2019

(54) DISPLAY DEVICE

(71) Applicant: Japan Display Inc., Minato-ku (JP)

(72) Inventors: Isao SUZUMURA, Minato-ku (JP); Yohei YAMAGUCHI, Minato-ku (JP); Hajime WATAKABE, Minato-ku (JP); Akihiro HANADA, Minato-ku (JP); Hirokazu WATANABE, Minato-ku (JP); Marina SHIOKAWA, Minato-ku (JP)

(73) Assignee: Japan Display Inc., Minato-ku (JP)

(21) Appl. No.: 15/929,125

(22) Filed: Apr. 18, 2019

Related U.S. Application Data
(62) Division of application No. 15/923,026, filed on Mar. 16, 2018.

(30) Foreign Application Priority Data
Mar. 29, 2017 (JP) 2017-064924

(51) Int. Cl. H01L 27/12; H01L 29/49; H01L 21/02; H01L 29/786; H01L 29/66; H01L 21/4763; H01L 21/465

(52) U.S. Cl. CPC H01L 27/1225; G02F 1/136227; H01L 21/02565; H01L 27/124; H01L 29/78648; H01L 27/1218; H01L 27/1266; H01L 27/127; H01L 21/02178; H01L 21/0217; H01L 21/02164; H01L 29/7869; H01L 29/66969; H01L 21/47635; H01L 21/465; H01L 29/4983; H01L 29/4908

(57) ABSTRACT

A display device to improve reliability of the TFT of the oxide semiconductor, including: a substrate including a display area where plural pixels are formed, the pixel includes a first TFT of a first oxide semiconductor; a first gate insulating film is formed on the first oxide semiconductor, a gate electrode is formed on the first gate insulating film, an interlayer insulating film is formed over the gate electrode; the gate insulating film includes a first silicon oxide film, the gate electrode includes a first gate layer made of a second oxide semiconductor and a second gate layer made of metal or alloy; the interlayer insulating film has a first interlayer insulating film including a second silicon oxide film, and a second interlayer insulating film including a first aluminum oxide film on the first interlayer insulating film.

### CROSS-REFERENCE TO RELATED APPLICATIONS

The present application is a Division of U.S. patent application Ser. No. 15/923,026, filed Mar. 16, 2018, now pending, which claims priority from Japanese Patent Application JP 2017-064924 filed on Mar. 29, 2017, the entire disclosures of both of which are hereby incorporated by reference into this application.

### BACKGROUND OF THE INVENTION

### Field of the Invention

### (1) Field of the Invention

The present invention relates to a display device comprising TFTs (Thin Film Transistor) that use oxide semiconductors.

### (2) Description of the Related Art

A liquid crystal display device or an organic EL display device uses TFTs for switching elements in the pixels or for the built in driving circuits. The TFT uses one of a-Si (amorphous Silicon), poly-Si (poly Silicon) or oxide semiconductor as an active layer. The a-Si has low mobility; consequently, there are some problems to use the a-Si in the TFTs for the peripheral driving circuits. The poly-Si has high mobility, which is suitable for the TFTs for the peripheral driving circuits; however, the poly-Si has some problems for the switching TFTs in the pixels since it has rather bigger leak current. The oxide semiconductor has low leak current and the mobility is higher than the mobility of the a-Si; however, it has some problems of reliability in controlling defects in the semiconductor layer.

The patent document 1 (Japanese patent laid open 2012-15436) discloses the structure that the entire of the TFT, which comprises the oxide semiconductor and gate electrode, is covered by the inorganic insulating film of e.g. aluminum oxide, titanium oxide or indium oxide.

The patent document 2 (Japanese patent laid open 2015-92638) discloses the structure to suppress the gate leak caused by the tunnel effect when the gate insulating film becomes thin. The patent document 2 discloses to use the material of high dielectric constant as e.g. hafnium oxide, tantalum oxide laminated with silicon oxide, silicon nitride or aluminum oxide, etc. for the gate insulating film.

The patent document 3 (WO 2010/041686) discloses to sandwich the channel of the oxide semiconductor by the inorganic insulating film to stabilize the characteristics of the TFT. The patent document 3 discloses to use e.g. aluminum oxide, titanium oxide or indium oxide for the inorganic insulating film.

### SUMMARY OF THE INVENTION

Foldable or bendable liquid crystal display devices or organic EL display devices are expected to be in use. The substrate of such bendable display device is made of resin, like e.g. polyimide. Hereinafter the resin is represented by polyimide. A certain kind of polyimide changes its characteristics when temperature becomes higher than 350 centigrade; therefore, the temperature in manufacturing process of the display device that uses such polyimide should be 350 centigrade or less.

The amorphous Silicon (a-Si), which has been used conventionally, is formed by a low temperature process, however, it has a problem that: the mobility is low as 1 cm2/Vs, and it is difficult to control a variation of the threshold voltage. Poly-Silicon (Poly-Si) has a high mobility; however, it needs process temperature of 400 centigrade or more to form a high quality Poly-Si TFT.

In contrast, the TFT, which uses the oxide semiconductor, can have a mobility of about 10 cm2/Vs even if it is formed by a low temperature process. However, even the oxide semiconductor, it has a task to improve reliability when it is formed by a process temperature of 350 centigrade or less.

Examples of the oxide semiconductors are: IGZO (Indium Gallium Zinc Oxide), ITZO (Indium Tin Zinc Oxide), ZnON (Zinc Oxide Nitride), IGO (Indium Gallium Oxide), and so on. Since those semiconductors are transparent, they are sometimes called TAOS (Transparent Amorphous Oxide Semiconductor). By the way, for example, The ratio of the components of IGZO is generally In:Ga:Zn=1:1:1, however, in this specification, IGZO includes the one that deviated from the above ratio.

The initial characteristics of the TFT using the oxide semiconductor can be controlled by the amount of oxide in the oxide semiconductor or in the insulating film that contacts with the oxide semiconductor; however, controlling the reliability is difficult. Specific problem is that defects in the insulating layer increase when an amount of oxygen in the insulating layer increases. Therefore, conventionally, the initial characteristics and the reliability have been in a relation of trade off.

That problem becomes bigger for the TFT that the oxide semiconductor is made in low temperature.

The purpose of the present invention is to realize the TFT formed by the oxide semiconductor that satisfies both of the initial characteristics and the high reliability during the product life. The present invention solves the above problem; the concrete measures of the present inventions are as follows.

A display device comprising: a substrate including a display area where plural pixels are formed,
the pixel includes a first TFT of a first oxide semiconductor,
a first gate insulating film is formed on the first oxide semiconductor,
a gate electrode is formed on the first gate insulating film,
an interlayer insulating film is formed over the gate electrode,
the gate insulating film includes a first silicon oxide film,
the gate electrode includes a first gate layer made of a second oxide semiconductor and a second gate layer made of metal or alloy,
the interlayer insulating film has a first interlayer insulating film including a second silicon oxide film, and a second interlayer insulating film including a first aluminum oxide film on the first interlayer insulating film.

### BRIEF DESCRIPTION OF THE DRAWINGS

FIG. 1 is a plan view of a liquid crystal display device;

FIG. 2 is a cross sectional view, along the line A-A of FIG. 1;

FIG. 3 is a cross sectional view of the display area of the liquid crystal display device;

FIG. 4 is a cross sectional view of the first embodiment;

FIG. 5A is cross sectional view of the display device in a process to realize the structure of FIG. 4;

FIG. 5B is cross sectional view of the display device in a process following FIG. 5A to realize the structure of FIG. 4;

FIG. 5C is cross sectional view of the display device in a process following FIG. 5B to realize the structure of FIG. 4;

FIG. 5D is cross sectional view of the display device in a process following FIG. 5C to realize the structure of FIG. 4;

FIG. 5E is cross sectional view of the display device in a process following FIG. 5D to realize the structure of FIG. 4;

FIG. 5F is cross sectional view of the display device in a process following FIG. 5E to realize the structure of FIG. 4;

FIG. 5G is cross sectional view of the display device in a process following FIG. 5F to realize the structure of FIG. 4;

FIG. 5H is cross sectional view of the display device in a process following FIG. 5G to realize the structure of FIG. 4;

FIG. 6 is a cross sectional view of the second embodiment;

FIG. 7 is a cross sectional view of the third embodiment;

FIG. 8 is a cross sectional view of the fourth embodiment;

FIG. 9 is a cross sectional view of the display device according to the fifth embodiment;

FIG. 10 is a cross sectional view of the fifth embodiment;

FIG. 11 is a cross sectional view of the sixth embodiment;

FIG. 12 is a cross sectional view of the display area of the organic EL display device.

### DETAILED DESCRIPTION OF THE PREFERRED EMBODIMENTS

The present invention will be described in detail referring to the following embodiments. The invention is explained mainly in regard to the liquid crystal display device; however, the invention is equally applicable to the organic EL display.

### First Embodiment

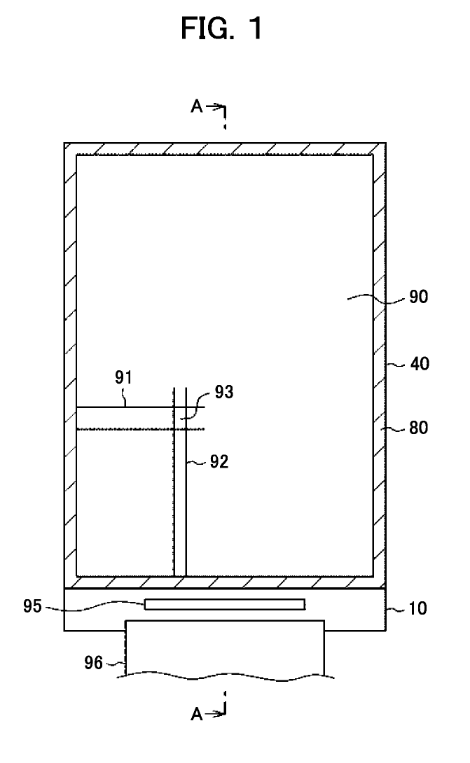

FIG. 1 is a plan view of a liquid crystal display device, which is used in e.g. the cellar phone, where the present invention is applied. In FIG. 1, the TFT substrate 10, in which plural pixels 93 are formed, and the counter substrate 40 are adhered by the seal material 80. The liquid crystal is sandwiched between the TFT substrate 10 and the counter substrate 40. The display area 90 is formed inside of the seal material 80. In the display area 90, the scan lines 91 extend in lateral direction and arranged in longitudinal direction; the video signal lines 92 extend in longitudinal direction and arranged in lateral direction The pixel 93 is formed in the area surrounded by the scan lines 91 and the video signal lines 92. In each of the pixels, the pixel electrode and the TFT, which controls the signals that are to be supplied to the pixel electrode, are formed. The TFT substrate 10 is made bigger than the counter substrate 40; the portion of the TFT substrate 10 that doesn't overlap with the counter substrate 40 is the terminal area. The driver IC 95 is installed in the terminal area; the flexible wiring substrate 96 is connected to the terminal area to supply signals and powers to the liquid crystal display device.

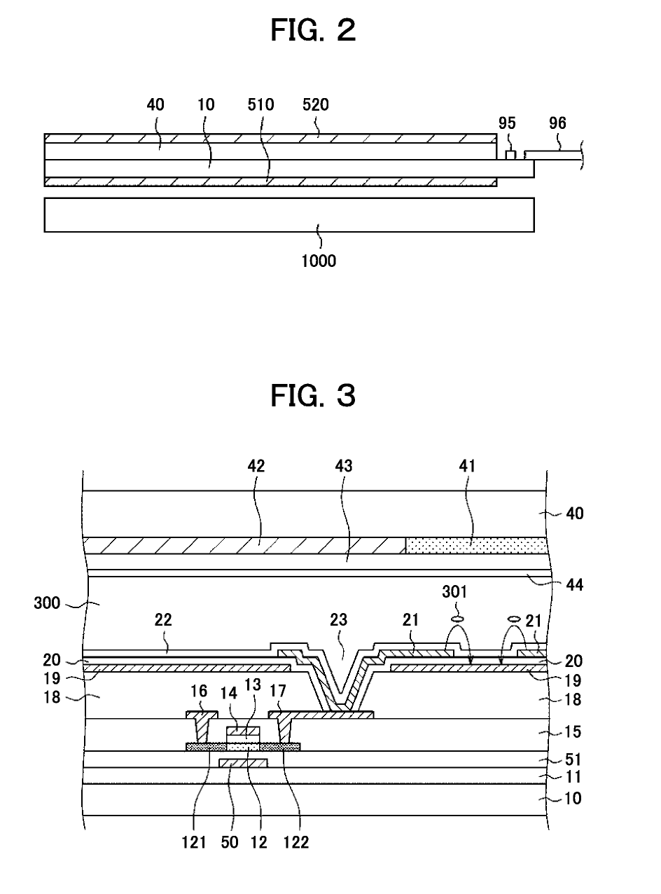

FIG. 2 is cross sectional view along the line A-A of FIG. 1. In FIG. 2, the TFT substrate 10 and the counter substrate 40 are overlapped to each other. The liquid crystal layer is omitted in FIG. 2 since the thickness of the liquid crystal layer is much thinner than the thicknesses of the TFT substrate 10 and the counter substrate 40. The portion where the TFT substrate 10 and the counter substrate 40 don't overlap is the terminal area where the driver IC 95 is installed and the flexible wiring substrate 96 is connected.

Since the liquid crystal is not self-illuminant, the back light 1000 is set at the rear side of the TFT substrate 10. Images are formed by controlling the light from the back light 1000 in each of the pixels. Since the liquid crystal controls only the polarized light, the lower polarizing plate 510 is adhered to the rear surface of the TFT substrate 10, and the upper polarizing plate 520 is adhered to on the counter substrate 40.

FIG. 3 is a cross sectional view of the display area 90 of the liquid crystal display device. In FIG. 3, the TFT substrate 10 is formed by resin, e.g. polyimide of a thickness of about 10 micrometer (hereinafter micron). Therefore, if the resin is used for the counter substrate, the display device of FIG. 3 is foldable or bendable. In the meantime, the present invention is applicable when the substrate is made of glass.

The undercoat 11 is formed on the TFT substrate 10 to prevent that impurities from the glass or the resin contaminate the semiconductor. The undercoat 11 is formed by a laminated film of a Silicon Oxide (SiO herein after) film and a Silicon Nitride (SiN) herein after) film; however, an Aluminum Oxide (AlO hereinafter) film may be laminated, too.

The TFT is formed on the undercoat 11. The TFT of FIG. 3 is a dual gate type TFT that has the bottom gate electrode 50 and the top gate electrode 14. The bottom gate electrode 50 is formed on the undercoat 11. The bottom gate insulating film 51 made of SiO is formed covering the bottom gate electrode 50. The first oxide semiconductor 12 is formed on the bottom gate insulating film 51.

The top gate insulating film 13 made of SiO is formed covering the first oxide semiconductor film 12. The top gate electrode 14 is formed on the top gate insulating film 13. By the way, both of the bottom gate electrode 50 and the top gate electrode 14 are preferably formed by Mo or W or alloys of those metals. Absorption of oxygen by Mo or W, etc. is lower than that of Ti, Al, etc.

As will be explained later, one of the characteristics of the present invention is to form the second oxide semiconductor between the top gate electrode 14, which is made of metal, and the top gate insulating film 13. The second oxide semiconductor supplies oxygen to the first oxide semiconductor 12, which constitutes the TFT.

The top gate electrode 14, the second oxide semiconductor 141, which is explained later, the top gate insulating film 13 are patterned using the same resist. After the top gate insulating film 13 is patterned, SiH₄ is flowed on the first oxide semiconductor to reduce the first oxide semiconductor to give conductivity, consequently, forming the drain area 121 and the source area 122 are formed in the first oxide semiconductor 12. The conductivity to the first oxide semiconductor 12 may be given by exposing the first oxide semiconductor 12 in the Ar plasma or in the N₂ plasma.

After that, the interlayer insulating film 15 is formed covering the top gate electrode 14 and the bottom gate insulating film 51. The interlayer insulating film 15 can be formed by the SiO film or a laminated film of the SiO film and the SiN film. Then, through holes are formed in the interlayer insulating film 15, subsequently, the drain electrode 16 and the source electrode 17 are formed in those through holes.

The organic passivation film 18 is formed covering the interlayer insulating film 15, the drain electrode 16 and the source electrode 17. Since the organic passivation film 18 has a role as a flattening film, it is made as thick as 2 micron to 4 micron. The through hole 23 is formed in the organic passivation film 18 to connect the pixel electrode 21 and the source electrode 17 of the TFT.

The common electrode 19 is formed in a solid plane shape on the organic passivation film 18. The capacitive insulating film 20 of SiN is formed covering the common electrode 19; the pixel electrode 21 is formed on the capacitive insulating film 20. The capacitive insulating film 20 is so called because a holding capacitance is formed between the common electrode 19 and the pixel electrode 21 via the capacitive insulating film 20. The alignment film 22 is formed covering the pixel electrode 21 for an initial alignment of the liquid crystal molecules 301. The pixel electrode is stripe shaped or comb shaped in a plan view. When the voltage is applied to the pixel electrode 21, the line of force as depicted by arrows in FIG. 3 is generated, whereby the liquid crystal molecules 301 are rotated, thus the transmittance of the light from the back light is controlled in a pixel.

In FIG. 3, the counter substrate 40 is set to sandwich the liquid crystal layer 300 with the TFT substrate 10. On the inner side of the counter substrate 40, the color filter 41 is formed corresponding to the pixel electrode 21 to form the color images. The black matrix 42 is formed between the color filters 41 to improve the contrast of the images. The overcoat film 43 is formed covering the color filter 41 and the black matrix 42. The overcoat film 43 prevents that the pigments in the color filter 41 goes out and contaminates the liquid crystal layer 300. The alignment film 44 is formed covering the overcoat film 43.

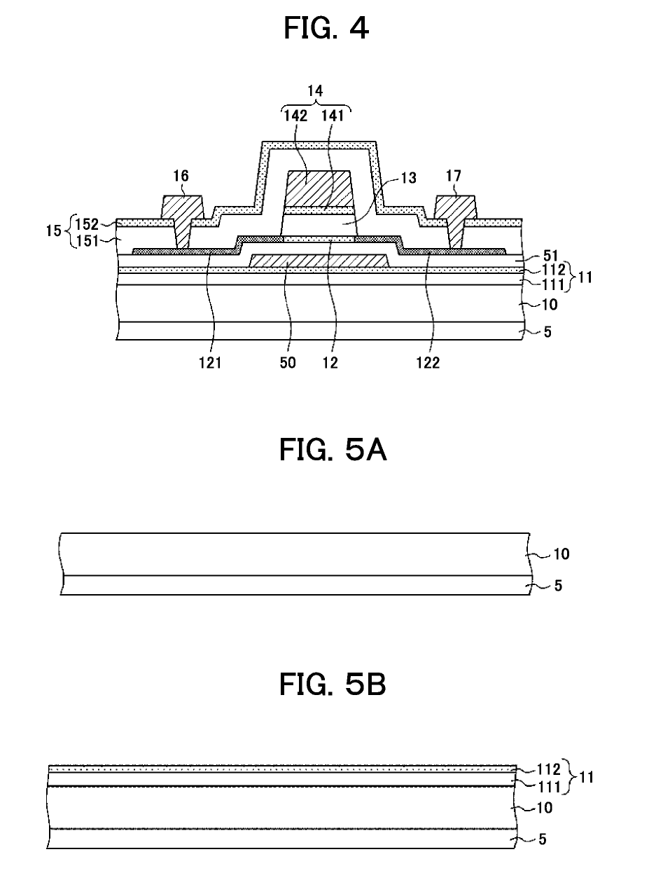

FIG. 4 is a cross sectional view of the first embodiment of the present invention. FIG. 4 corresponds to the structure before the organic passivation film is formed in FIG. 3. In FIG. 4, the polyimide substrate of about 10 micron thickness is used for the TFT substrate 10. Such a thin polyimide is flexible, thus, it is difficult to go through the manufacturing process. Therefore, the support substrate 5 made of glass is attached under the polyimide substrate 10. In FIG. 4, for convenience of the figure, the support substrate 5 is drawn thinner than the polyimide substrate 10, however, actually, the support substrate 5 is thicker than the polyimide substrate 10 since the support substrate give rigidity to the TFT substrate 10 for the manufacturing process. In the real process, the material for the polyimide is coated on the support substrate 5 made of glass, then baked to form polyimide substrate 10. After all the necessary processes are completed, the support substrate 5 is removed from the polyimide substrate 10 through laser ablation.

The undercoat 11 is formed on the polyimide substrate 10. The undercoat 11 of FIG. 4 is constituted by the first layer 111 made of a laminated film of SiN/SiO and the second layer 112 made of the first AlO. The SiO layer has good adherence characteristics with the polyimide; The SiN layer is a superior blocker against moisture. The AlO film 112 has good blocking characteristics against many gases as well as moisture; further it can be a supplier of oxygen to the first oxide semiconductor 12, which is formed later on. The thickness of the first AlO film 112 is 1 nm to 20 nm. The thickness of the first film 111 of SiN/SiO is e.g. 50 nm/50 nm.

The bottom gate electrode 50 is formed on the AlO film 112; the bottom gate insulating film 51 is formed covering the bottom gate electrode 50. The first oxide semiconductor 12 made of e.g. IGZO is formed on the bottom gate insulating film 51. The thickness of the first oxide semiconductor 12 is 10 nm to 70 nm. In FIG. 4, the top gate insulating film 13, the second oxide semiconductor 141 and top gate electrode 142 are formed on the first oxide semiconductor 12. Those three layers are patterned using the same mask.

After patterning of the top gate insulating film 13 and other films are patterned, SiH₄ is flowed on the first oxide semiconductor 12 for reducing the first oxide semiconductor to give conductivity, thus, forming the drain area 121 and the source area 122. After that, the interlayer insulating film 15 is formed covering the drain area 121, the source area 122 and the top gate electrode 14. In FIG. 4, the interlayer insulating film 15 is formed by the first layer 151 made of SiO and the second layer 152 made of AlO. The thickness of the SiO layer is e.g. 300 nm and the thickness of the AlO layer is e.g. 50 nm. The thickness of the AlO layer can be 1 nm to 50 nm. The first layer 151 can be a laminated film of the SiO layer and the SiN layer. After that, through holes are formed in the interlayer insulating film 15 to connect the drain electrode 16 and the drain area 121, and to connect the source electrode 17 and the source area 122.

The characteristics of FIG. 4 is that the second oxide semiconductor 141 is formed between the upper layer 142 of the top gate electrode, which is made of metal, and the top gate insulating film 13. The material for the second semiconductor 141 can be the same as the material for the first oxide semiconductor 12 or can be the different one. The thickness of the second oxide semiconductor is 1 nm to 30 nm.

The variation of the characteristics of the TFT of the first oxide semiconductor 12 is caused by that oxygen is not stably maintained in the first semiconductor 12. In the present invention, oxygen is supplied to the first semiconductor 12 from the second oxide semiconductor 141, in addition, the second semiconductor prevents that the oxygen moves from the first oxide semiconductor 12 to the gate electrode 14.

Yet another characteristics of the present invention is to sandwich the first oxide semiconductor 12 by the upper layer 112 made of AlO of the undercoat 11 and the upper layer 152 made of ALO of the interlayer insulating film 15; thus, to block the external influence like moisture to the first oxide semiconductor 12, in addition, to prevent that the oxygen goes out from the first oxide semiconductor.

By the way, if the first oxide semiconductor 12 is annealed at high enough temperature, the variation of the characteristics of the first oxide semiconductor 12 can be suppressed. However, when polyimide is used for the TFT substrate 10, it is difficult to raise the annealing temperature higher than 350 centigrade. According to the structure of the present invention, the TFT of the oxide semiconductor having stable characteristics can be realized even the annealing temperature is 350 degree or less. In other words, the variation in the characteristics of the first oxide semiconductor 12 can be suppressed even when the oxide semiconductor is not annealed at a temperature of more than 350 centigrade.

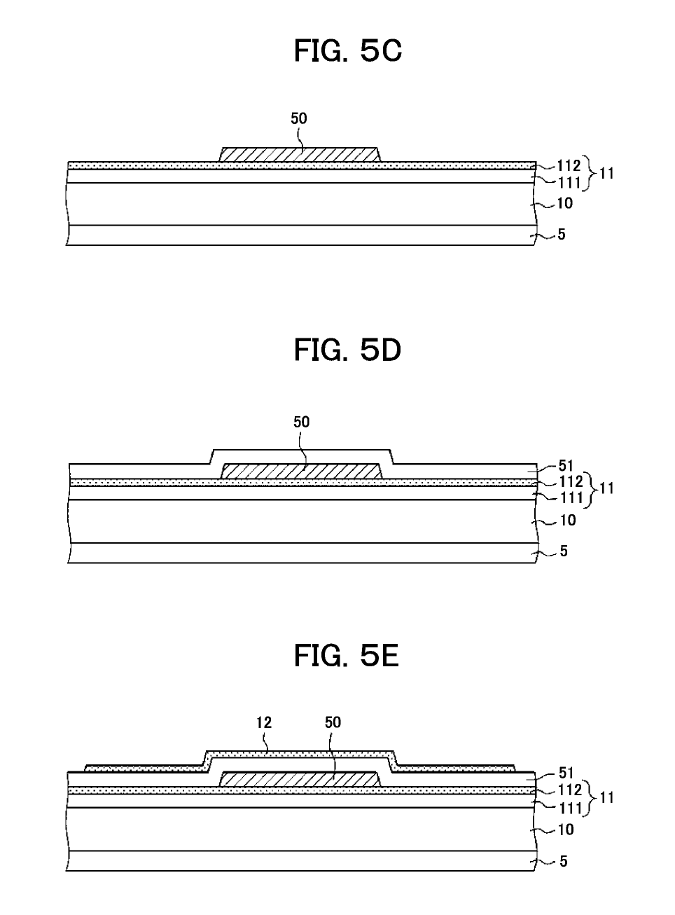

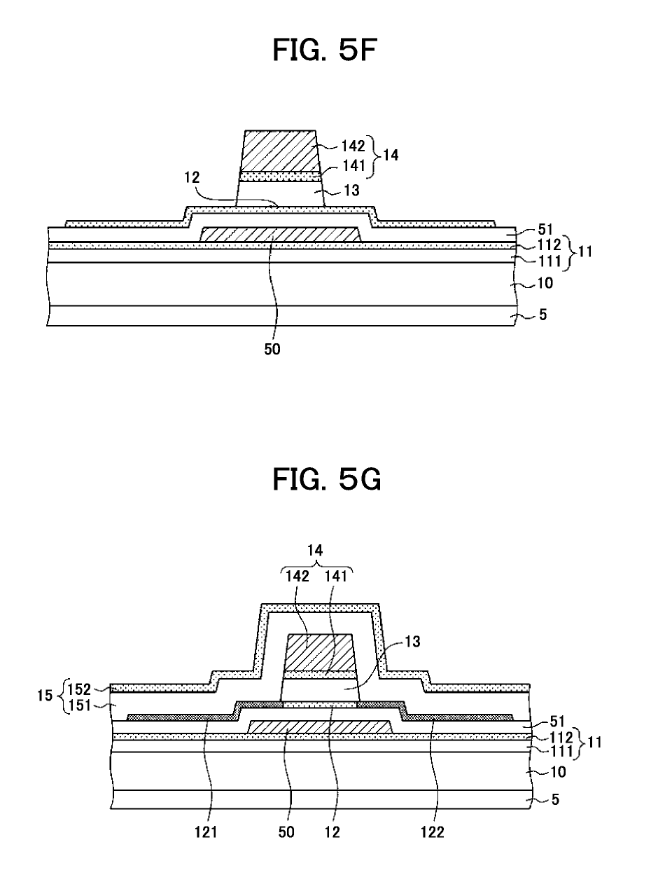

FIGS. 5A to 5H explain the process to realize the structure of FIG. 4. FIG. 5A shows the material of polyimide is coated on the glass 5; then the material is baked to form the polyimide substrate 10. FIGS. 5A to 5H show the cross sectional view of the display device in the processes, the support substrate exists made of e.g. glass for the passage of the manufacturing process. The support substrate 5 is removed from the polyimide substrate 10 by e.g. laser ablation after the processes are completed. The thickness of the polyimide is e.g. 10 micron. In FIGS. 5A to 5H, the thickness of the support substrate 5 is depicted thinner than the polyimide substrate 100; however, it is just for convenience of the drawing, actually, the support substrate 5 is thicker than the polyimide substrate 10

FIG. 5B shows that the undercoat 11 is formed on the polyimide substrate 10. The undercoat 11 comprises: the first layer 111 formed by a laminated film of the SiO layer and the SiN layer, and the second layer 112 made of AlO layer. The lower layer of the first layer 111 is the SiO layer; the upper layer is the SiN layer. The SiO layer is set as the under layer since it has a good adhesion with the polyimide. The thickness of each of the SiO layer and the SiN layer is 50 nm; the thickness of the AlO layer is e.g. 20 nm.

FIG. 5C shows the bottom gate electrode 50 is formed on the undercoat 11 and patterned. The material for the bottom gate electrode 50 is preferably Mo base or W base, or MoW alloys. The metal of Mo base or W base absorbs less oxygen compared to other metals; thus, gives less adverse effect to the first oxide semiconductor 12. The thickness of the bottom gate electrode 50 is e.g. 50 nm.

FIG. 5D is a cross sectional view that shows the bottom gate insulating film 51 is formed covering the bottom gate electrode 50. The bottom gate insulating film 51 is a laminated film of the SiO layer and the SiN layer; the SiN layer is a lower layer and the SiO layer is an upper layer. The thickness of the SiN layer is e.g. 50 nm; the thickness of the SiO layer is e.g. 200 nm. The bottom gate insulating film 51 can be formed only by the SiO layer.

FIG. 5E is a cross sectional view that shows the first oxide semiconductor 12 is formed on the bottom gate insulating film 51 and is patterned. The first oxide semiconductor 12 is formed by e.g. IGZO. The thickness of the first oxide semiconductor 12 is e.g. 10 nm to 70 nm. When the oxide semiconductor is patterned by wet etching, the oxalic based solution is used. When the oxide semiconductor 12 is patterned by dry etching, the Cl (chlorine) base gases are used.

FIG. 5F is a cross sectional view that shows the top gate insulating film 13 and the top gate electrode 14 are formed on the first oxide semiconductor 12. In FIG. 5F, the top gate insulating film 13 and the top gate electrode 14 are patterned. The feature of the present invention is to form the second oxide semiconductor 141 between the top gate insulating film 13 and the top gate electrode 142, which is made of metal. The second oxide semiconductor 141 can supply oxygen to the first oxide semiconductor 12.

The top gate electrode 142, the second oxide semiconductor 141 and top gate insulating film 13 are etched continuously. One example of the patterning is that: if the top gate electrode 142 is made by Mo base or W base, the top gate electrode 142 is etched by dry etching using fluorine (F) base gas; then the second oxide semiconductor 141 is etched using oxalic acid; finally, the top gate insulating film 13 is etched by dry etching using fluorine (F) base gas, again. The same resist can be used in those processes.

In FIG. 5F, the first oxide semiconductor is 12 exposed except at the portion where it is covered by the top gate electrode 13. In this state, when the SiH₄ is flowed, the exposed portions 121, 122 of the first oxide semiconductor 12 are reduced, and consequently, reveal conductivity. Those reduced regions are used as the drain area 121 and the source area 122. Another method to form the drain area 121 and the source area 122 in the first oxide semiconductor 12 is to expose the uncovered area of the first oxide conductor to the Ar plasma or N₂ plasma instead of reducing the first oxide semiconductor 12 by hydrogen. FIG. 5G is a cross sectional view that shows the interlayer insulating film 15 is formed covering the top gate electrode 14, the drain area 121 and the source area 122 of the first oxide semiconductor 12. By the way, the shaded areas are the drain area 121 and the source area 122 of the first oxide semiconductor 12 in FIG. 5G. The interlayer insulating film 15 is formed by the first layer 151 made of SiO and the second layer 152 made of AlO. The thickness of the first layer 151 made of SiO is e.g. 300 nm; the thickness of the second layer 152 made of AlO is 1 nm to 20 nm.

As depicted in FIG. 5G, the first oxide semiconductor is sandwiched by AlO 112 and AlO 152. Since AlO has superior barrier characteristics, oxygen is confined between AlO 112 and AlO 152; thus, oxygen is suppressed from getting out of the first oxide semiconductor 12.

By the way, both of the top gate insulating film 13 and the interlayer insulating film 15 are made of SiO; however, the SiO of the top gate insulating film 13 has a structure that can supply more oxygen, consequently, the characteristics of the channel can be stabled.

FIG. 5H is a cross sectional view that shows the through holes 26, 27 are formed in the interlayer insulating film 15 to expose the drain area 121 and the source area 122 of the first oxide semiconductor 12. After that the drain electrode 16 and the source electrode 17 are formed; then the structure of FIG. 4 is completed. By the way, the drain electrode 16 and the source electrode 17 are made of the same material as the video signal line, e.g. a laminated film of Ti/Al/Ti.

The first oxide semiconductor 12, which is sandwiched by the bottom gate insulating film 51 and the top gate insulating film 13, maintains its characteristics by oxygen supplied from the SiO constituting the bottom gate insulating film 51 and from the SiO constituting the top gate insulating film 13. Generally, the SiO, which can supply oxygen, has many defects. However, the SiO that has many defects deteriorates the reliability of the oxide semiconductor.

That is to say, if more oxygen is supplied from the SiO to improve the characteristics of the TFT, initial characteristics can be satisfied; however, the reliability in product's life is decreased. In other words, the initial characteristics and the reliability during the product's life are in self-contradiction.

On the contrary, according to the present invention, the second oxide semiconductor 141 is formed on the top gate insulating film 13, which is made of SiO; oxygen is supplied to the first oxide semiconductor 12 from the second oxide semiconductor 141, therefore, many defects in the bottom gate insulating film 51 and in the top gate insulating film 13 are not necessary.

Further, according to the present invention, the TFT including the first oxide semiconductor 12 is sandwiched by the AlO films, which have superior barrier characteristics; thus, the oxygen is suppressed from getting out of the first oxide semiconductor 12. Thus, deterioration of the characteristics in the first oxide semiconductor 12 can be avoided. The characteristics of the SiO that constitutes the bottom gate insulating film 51 and the top gate insulating film 13 is as follows:

Firstly, the defect density is low; concretely, 1×10¹⁸ (spins/cm³) or less by ESR (Electrode Spin resonance) analysis. Secondly, enough oxygen must be supplied to maintain the characteristics of the first oxide semiconductor; concretely, in TDS (Thermal Desorption Spectrometry) analysis, when M/z=32, the desorption of oxygen (O₂) is 1×10¹⁵ (molecules/cm²) or more at the temperature of 100 to 250 centigrade. Conventional structure was not able to satisfy the above two characteristics simultaneously.

Thirdly, desorption of gases other than oxygen is low. The TFT substrate goes through several processes; the gases other than oxygen are absorbed by the SiO layer during the processes. Those gases deteriorate the characteristics of the first oxide semiconductor 12. Thus, the reliability of the first oxide semiconductor 12 can be improved by using the SiO of low defects for e.g. the top gate insulating film 13.

Among the gases used in the processes, if N₂O is evaluated as a concrete example: in TDS analysis, provided M/z=44, the desorption of N₂O is 8×10¹³ (molecules/cm²) or less at the temperature of 100 to 400 centigrade.

The above explained characteristics are of the SiO that constitutes the top gate insulating film 13 or bottom gate insulating film 51 in a completed display device. As to the measurement of the silicon oxide film of the upper gate insulating film 13 in a completed display device, the upper layers formed over the silicon oxide film 13 are taken away in FIG. 4; then, the ERS or the TDS are applied. As the same token, as to the measurement of the silicon oxide film of the bottom gate insulating film 51 in a completed display device, the upper layers formed over the silicon oxide film 51 are taken away; after that, the ERS or the TDS are applied to the silicon oxide film 51.

### Second Embodiment

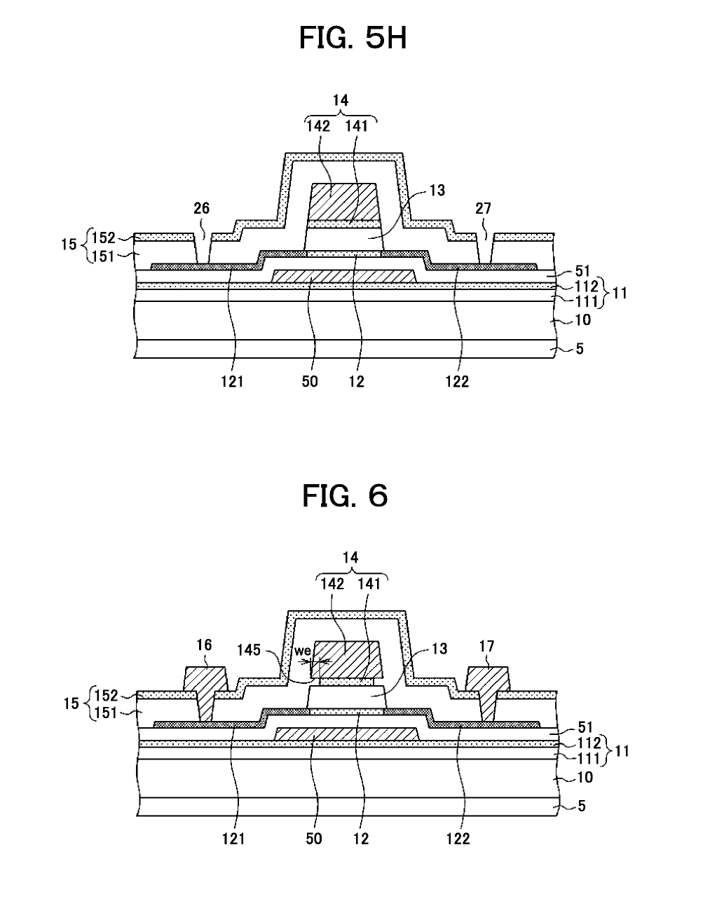

FIG. 6 is a cross sectional view of the second embodiment. FIG. 6 differs from FIG. 4 in that the second oxide insulating film 13 is side etched, thus the eaves of the metallic top gate electrode 142 is formed at the second oxide semiconductor 141.

In FIG. 6, the top gate insulating film 13 is patterned e.g. by dry etching using fluoride based gases, as explained in FIG. 5F. During the sputtering, the drain area 121 and the source area, which are conductive, are exposed to the plasma; a part of the surfaces of them are sputtered, too. The sputtered material of the drain area 121 and the source area 122 is deposited on the side surface of the top gate insulating film 13, there can be a chance of leak between the top gate electrode 14 and the drain area 121 or the source electrode 122.

According to the structure of FIG. 6, the eaves 145 of the top gate electrode 142, which is formed by side etching of the second oxide semiconductor 141, forms a gap between the side surface of the metallic top gate electrode 142 and the side surface of the top gate insulating film 13; thus, the gate leak can be suppressed.

In FIG. 6, the amount of side etching, namely, length we of the eaves 145 is 5 nm to 20 nm. Approximately 5 nm in length of the eaves is necessary to avoid the gate leak. On the other hand, the amount of side etching, namely, the length of eaves should be 20 nm or less to avoid formation of voids or pores, which can be generated at the side etched portion of the second oxide semiconductor 141 when the interlayer insulating film 15 is formed.

### Third Embodiment

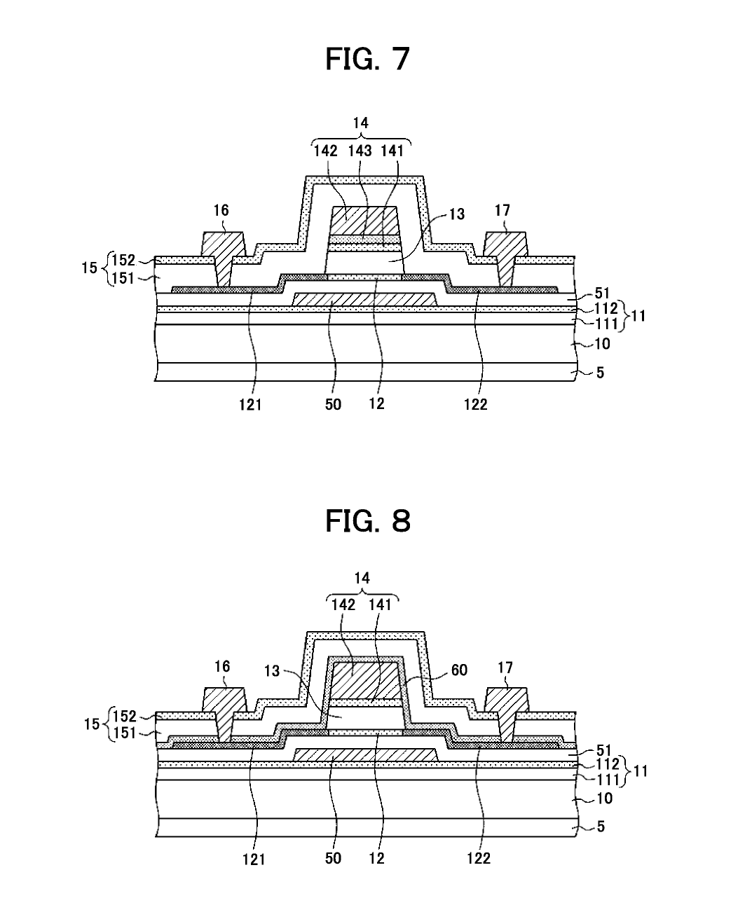

FIG. 7 is a cross sectional view of the third embodiment. FIG. 7 differs from FIG. 4 in that the top gate electrode 14 is a three layer structure of the second oxide semiconductor 141, the metal compound 143 and the metal 142 of e.g. MoW. The roles of the second oxide semiconductor 141 and the metal 142 have been explained in the first embodiment. The metal compound 143 is constituted either by the metal nitride of e.g. titanium nitride (TiN), or metal oxide of e.g. AlO or TiO.

The oxygen from the second oxide semiconductor 141 is absorbed by the gate metal layer 142, thus, supply of oxygen from the second oxide semiconductor 141 decreases. The role of the metal compound 143 is to prevent a decrease in supplying oxygen from the second oxide semiconductor 141 to the first oxide semiconductor 12. In other words, the metal compound works as a barrier layer that prevent the oxygen of the second oxide semiconductor 141 from moving to the reverse direction.

A thickness of the metal compound 143 when it is formed by a metal nitride as TiN is e.g. 10 nm to 50 nm. A thickness of the metal compound 143 when it is formed by a metal oxide as AlO is e.g. 5 nm to 50 nm. In the meantime, the metal compound 143 can be an insulating film, however, it is taken as a part of the top gate electrode 14 in this specification.

### Fourth Embodiment

FIG. 8 is a cross sectional view of the fourth embodiment. FIG. 8 differs from FIG. 4 in that the barrier layer 60 is formed covering the top gate electrode 14 and the first oxide semiconductor 12, 121, 122. The barrier layer 60 prevents oxygen of the first semiconductor from going upward direction. The barrier layer 60 is made of e.g. SiN, AlO or TiN. When the barrier layer 60 is formed by e.g. metal nitride as e.g. SiN or TiN, the thickness is e.g. 10 nm to 50 nm. When the barrier layer is formed by e.g. metal oxide as e.g. AlO, the thickness is e.g. 5 nm to 50 nm.

### Fifth Embodiment

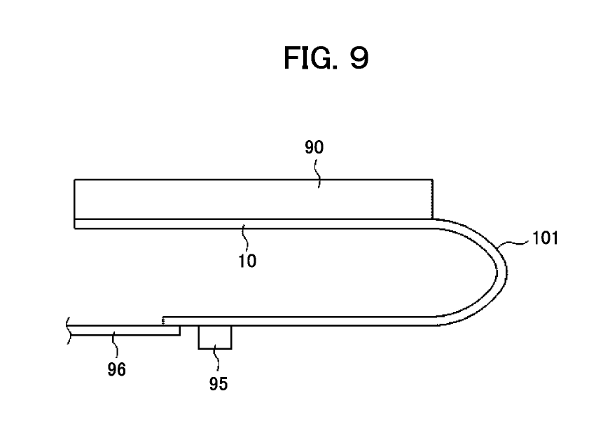

Certain kind of the flexible display devices, as depicted in FIG. 9, is that the display area 90 is flat, however, the terminal area 101 is folded; thus, outer size of the display device is made smaller in total. In FIG. 9, the substrate 10 extended from the display area 90 is folded to the back of the display area 90. The driver IC 95 is installed in the folded terminal area and the flexible wiring substrate 96 is connected to the folded terminal area 101. If the display device is formed by polyimide substrate of a thickness of 10 micron, it can be bent in a radius curvature of 0.5 mm or less, easily.

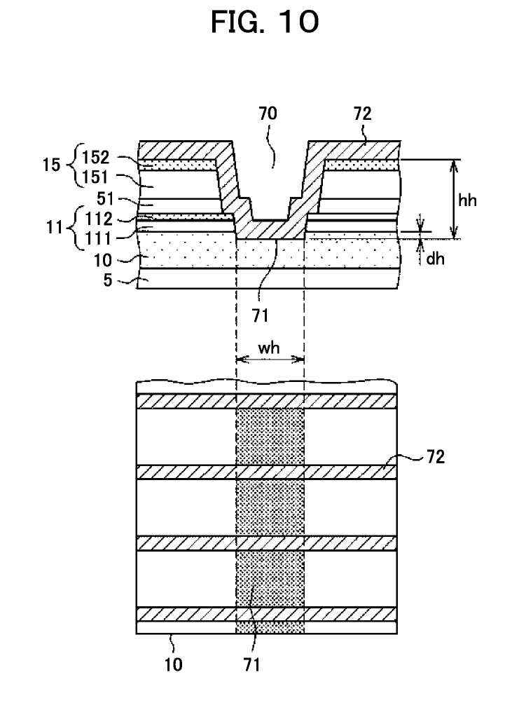

When the terminal area is bent in a small radius, a dislocation between the substrate 10 and the wiring 72, between the substrate 10 and several insulating films, or between the wirings and the insulating films can occur. FIG. 10 shows the structure of the terminal area 101 that countermeasures this problem. In FIG. 10, the upper figure is a cross sectional view and the lower figure is a plan view of the terminal area 101.

The undercoat 11, the bottom gate insulating film 51, the interlayer insulating film 15, etc. are formed on the substrate 10 in FIG. 10. A groove like through hole is formed extending in a perpendicular direction to the bending direction; and further, the groove like recess 71 is formed on the surface of the substrate 10; thus, the groove 70 is formed. The groove like through hole in the insulating films and the groove like recess 71 on the substrate 10 can be formed in one process.

After that, the wiring 72 is formed across the groove 70. The insulating films are cut at the groove like through hole, thus, the stress is released at this portion. In addition, the groove like recess 71 on the substrate 10 further reduces the bending stress. Therefore excessive stress in the insulating films are suppressed even the terminal area 101 is bent in a small radius curvature; therefore, dislocation between the wiring 72 and the insulating layers and between the insulating layers and the substrate 10, etc. can be avoided.

Bending in the terminal area 101 in FIG. 9 originates from the groove 70 in FIG. 10. Therefore, a radius of curvature in this area can be made small easily, further excessive stresses in the insulating films and in the wiring are not generated.

In FIG. 10, the depth of the groove 70 is a summation of thicknesses of the insulating films and the depth of the recess 71 formed on the substrate 10; this makes the depth of the groove is e.g. 1 micron. Out of them, the depth dh of the groove like recess on the substrate 10 is 300 nm. The width wh of the groove 70, when it is measured at the bottom of the groove 70 is 1 micron to ten micron. The depth of the groove 71 on the substrate 10 can be measured by a measuring instrument for surface roughness like SURFCOM (trade mark); the surface view of the groove can be observed by a microscope.

### Embodiment 6

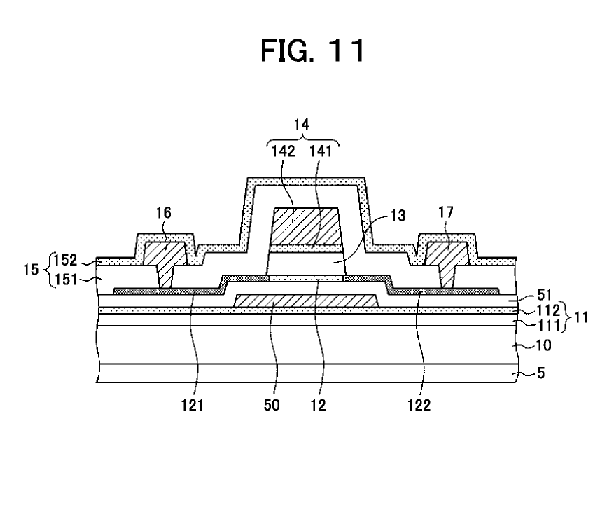

FIG. 11 is a cross sectional view of the sixth embodiment of the present invention. FIG. 11 differs from FIG. 4 in that the upper layer 152 of the interlayer insulating film 15 is formed by AlO covering the drain electrode 16 and the source electrode 17. Namely, through holes for the drain electrode 16 and for the source electrode 17 are formed only in SiO that is the lower layer 151 of the interlayer insulating film 15.

Pattering of the drain electrode 16 and the source electrode 17 is made by dry etching. When the metal, other than the drain electrode 16 or the source electrode 17, is removed by dry etching, the layer under the metal gets damages. In the structure of FIG. 4, the layer 152 made by AlO, which is an upper layer of the interlayer insulating film 15, gets damage. Since the upper layer 152 made of AlO is made thin as 1 nm to 20 nm, there is a possibility that the AlO film is removed at the same time when the drain electrode 16 and the source electrode 17 are patterned. The AlO film, however, has an important role as a barrier, thus, if it is dissipated or made damage, a reliability of the first oxide semiconductor 12 gets severe damage. Therefore, in the present invention, the upper layer 152 made of AlO of the interlayer insulating film 15 is formed after patterning of the drain electrode 16 or the source electrode 17; thus, damages in the AlO film 152 are avoided. Consequently, the reliability of the TFT of the oxide semiconductor is maintained.

### Seventh Embodiment

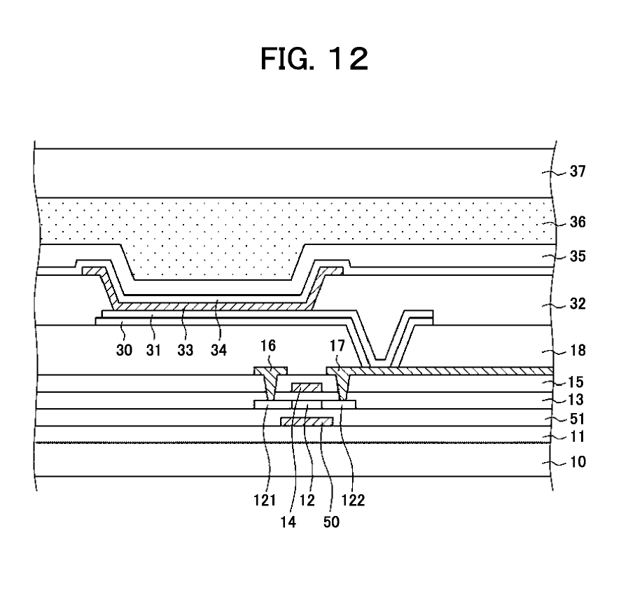

The above explanations are made in regard to the liquid crystal display device as depicted in FIGS. 1 to 3. The present invention, however, is applicable to the organic EL display device as well as to the liquid crystal display device. FIG. 12 is a cross sectional view of the display area of the organic EL display device. In FIG. 12, the following structure is the same as FIG. 3 of the liquid crystal display device; namely, the TFT is formed on the TFT substrate 10; the organic passivation film 18 is formed on the TFT; the through hole is formed in the organic passivation film 18. The undercoat 11 is formed on the TFT substrate to avoid contamination by impurities from the glass or the resin to the semiconductor layer. The undercoat is a laminated film of the SiO layer and the SiN layer; the AlO film can be laminated on them.

Therefore, the structure of the TFT of the oxide semiconductor, explained in the embodiments 1-6, is applicable to the organic EL display device.

In FIG. 12, the refection electrode 30 is formed on the organic passivation film 18; the oxide conductive film as ITO (Indium Tin Oxide) for the anode 31 is formed on the reflection electrode 30. The bank 32 is formed by e.g. acrylic resin covering the anode 31 and the organic passivation film 18. In the hole of the bank 32, the organic EL layer 33 is formed as a light emitting layer on the anode 31. The organic EL layer 33 is constituted by plural layers; the thickness is about several hundred nm even all the layers are combined, namely, each of the layers is very thin. The bank 32 is made so that the organic EL layer doesn't have step disconnection at the edge of the anode 31 or the reflection electrode 30.

In FIG. 12, the upper electrode as a cathode 34, which is made of the oxide conductive film as e.g. ITO or IZO (Indium Zinc Oxide), or a thin metal, is formed over the organic EL layer 33. Since the organic EL layer 33 is decomposed by moisture, protective film 35 is formed by e.g. SiN to prevent the intrusion of moisture.

Since the organic EL display device uses the reflection electrode 30, the external light is reflected, which deteriorates the visibility of the screen. To prevent this phenomenon, the circular polarizing plate 37 is adhered to the screen e.g. via the adhesive 36.

As described above, the structure of the organic EL display device has the same structure as the liquid crystal display device up to formation of the drain electrode 16 and the source electrode 17; thus, the present invention, explained in the embodiments 1-6, is applicable to the organic EL display device, too.

In the above explanations, the TFT is a dual gate type, however, the present invention is applicable to the TFT of a top gate type and to the TFT of a bottom gate type.

For example, if the TFT is a top gate type, the first oxide semiconductor is formed on the insulating film 51 in FIG. 5D.

If the TFT is a bottom gate type, the bottom gate can be a laminated film of two layers. The upper layer, which is nearer to the first oxide semiconductor, is formed by the second oxide semiconductor, the lower layer is formed by metal of Mo base or W base.

What is claimed is:

1. A display device comprising:
a substrate including a display area where plural pixels are formed, wherein, for each of the plural pixels:
said each of the plural pixels includes a first TFT of a first oxide semiconductor,
a gate insulating film is formed on the first oxide semiconductor,
a gate electrode is formed on the gate insulating film,
an interlayer insulating film is formed over the gate electrode,
the gate insulating film includes a first silicon oxide film,
the gate electrode includes a first gate layer made of a second oxide semiconductor and a second gate layer made of metal or alloy,
an eaves of the second gate layer is formed to the second oxide semiconductor,
a distance between a drain region and a source region of the first oxide semiconductor is wider than a width of the second oxide semiconductor in cross sectional view, and
a defect density in the first silicon oxide film is 1×10¹⁸ (spins/cm³) or less by ESR (Electron Spin resonance) analysis, and
the interlayer insulating film has a first interlayer insulating film including a second silicon oxide film, and a second interlayer insulating film including a first aluminum oxide film on the first interlayer insulating film.

2. The display device according to claim 1,
wherein the gate insulating film is formed only under the gate electrode.

3. The display device according to claim 1,
wherein a barrier layer, made of a metal nitride, metal oxide or silicon nitride, is formed between the gate electrode and the interlayer insulating film.

4. The display device according to claim 1,
wherein a first through hole is formed in the first interlayer insulating film and the second interlayer insulating film to connect a drain electrode and a drain area of the first oxide semiconductor,
a second through hole is formed in the first interlayer insulating film and the second interlayer insulating film to connect a source electrode and a source area of the first oxide semiconductor, and
the drain electrode and the source electrode extend on the second interlayer insulating film.

5. The display device according to claim 1,
wherein an undercoat, which includes a second aluminum oxide film, is formed on or above the substrate, and
the first oxide semiconductor is formed on the second aluminum oxide film or above the second aluminum oxide film.

6. The display device according to claim 1,
wherein the first silicon oxide film has a desorption of oxygen that;
in TDS (Thermal Desorption Spectrometry) analysis, when M/z=32, the desorption of oxygen (O₂) is 1×10¹⁵ (molecules/cm²) or more at the temperature of 100 to 250 centigrade.

7. The display device according to claim 1,
wherein the first silicon oxide film has a desorption of oxygen that;
in TDS analysis, provided M/z=44, the desorption of N₂O is 8×10¹³ (molecules/cm²) or less at the temperature of 100 to 400 centigrade.

8. A display device comprising:
a substrate including a display area where plural pixels are formed, wherein, for each of the plural pixels:
said each of the plural pixels includes a first TFT of a first oxide semiconductor,
a first gate insulating film is formed on the first oxide semiconductor,
a first gate electrode is formed on the first gate insulating film,
an interlayer insulating film is formed over the first gate electrode,
the first gate insulating film includes a first silicon oxide film,
the first gate electrode includes a first gate layer made of a second oxide semiconductor and a second gate layer made of metal or alloy,
an eaves of the second gate layer is formed to the second oxide semiconductor,
a distance between a drain region and a source region of the first oxide semiconductor is wider than a width of the second oxide semiconductor in cross sectional view, and
a defect density in the first silicon oxide film is 1×10¹⁸ (spins/cm³) or less by ESR (Electron Spin resonance) analysis,
the interlayer insulating film has a first interlayer insulating film including a second silicon oxide film, and a second interlayer insulating film including a first aluminum oxide film on the first interlayer insulating film,
a second gate insulating film is formed under the first oxide semiconductor, and
a second gate electrode is formed under the second gate insulating film.

9. The display device according to claim 8,
the first gate insulating film is formed only under the first gate electrode.

10. The display device according to claim 8,
wherein an undercoat, which includes a second aluminum oxide film, is formed on the substrate, and
the second gate electrode is formed on the second aluminum oxide film.

11. The display device according to claim 1,
wherein the substrate is made of polyimide.
